(19) United States
(12) Patent Application Publication
(10) Pub. No.: US 2011/0090013 A1
(43) Pub. Date: Apr. 21, 2011

(54) FIELD-EFFECT TRANSISTOR AMPLIFIER

(75) Inventor: Kazuyuki IMAGAWA, Kanagawa (JP)

(73) Assignee: Renesas Electronics Corporation

(21) Appl. No.: 12/899,973

(22) Filed: Oct. 7, 2010

(30) Foreign Application Priority Data
Oct. 21, 2009 (JP) 2009-242072

(51) Int. Cl. H03F 3/04

(52) U.S. Cl. 330/296

(57) ABSTRACT

A field-effect transistor amplifier is provided, which can maintain excellent RF characteristics and, at the same time, can improve current variation. The field-effect transistor amplifier according to the present invention comprises a field-effect transistor which amplifies an input signal supplied to a gate terminal thereof and outputs the amplified signal from a drain terminal thereof, and a self-bias circuit coupled to a source terminal of the field-effect transistor. The self-bias circuit comprises a resistor, a capacitor, and an adjusting circuit which adjusts RF (high frequency) characteristics and DC (direct current) characteristics. The resistor, the capacitor, and the adjusting circuit are coupled in parallel with each other, and one end of each of them is coupled to the source terminal and the other end is coupled to a ground.

### CROSS-REFERENCE TO RELATED APPLICATIONS

The disclosure of Japanese Patent Application No. 2009-242072 filed on Oct. 21, 2009 including the specification, drawings and abstract is incorporated herein by reference in its entirety.

### BACKGROUND OF THE INVENTION

The present invention relates to a field-effect transistor amplifier, more specifically relates to a field-effect transistor amplifier which is suitable for use in a microwave band.

Up to now, an amplifier circuitry employed in the microwave frequency band has been proposed (for example, Patent Document 1-Patent Document 3). FIG. 7 illustrates a circuit diagram of an amplifier for use in the microwave band described in Patent Document 1. In the amplifier for use in the microwave band, a feedback circuit which comprises a resistor 902 and an inductor 903 is coupled between a collector and a base of a bipolar transistor 901. A self-bias circuit 930 which comprises a resistor 931 and a capacitor 932 is coupled between an emitter of the bipolar transistor 901 and a ground. Furthermore, the base of the bipolar transistor 901 is coupled to a power supply Vbb via a resistor 904, and the collector of the bipolar transistor 901 is coupled to a power supply Vcc via a resistor 905.

Patent Document 2 proposes and amplifier for use in the microwave band employing a field-effect transistor (henceforth also called as “FET (Field Emission Transistor)”) which aims at compensation of a temperature change. Patent Document 3 proposes an MMIC low-noise amplifier for use in the microwave band in which the reduction of part cost and assembly cost is realized by reducing the number of external parts.
(Patent Document 1) Japanese Patent Laid-open No. Hei 11(1999)-340747 (FIG. 13)
(Patent Document 2) Japanese Patent Laid-open No. 2002-171139
(Patent Document 3) Japanese Patent Laid-open No. 2003-110374

### SUMMARY OF THE INVENTION

In a microwave amplifier usable in a wide band employing an FET, excellent input return loss characteristics and gain characteristics in 50-880 MHz are required for use in a D-TV, for example. In addition, suppressing variation of drain current due to Vt variation of an FET is required in order to maintain a good yield. However, it was difficult to manage to balance the excellent band characteristics and the current variation characteristics.

The following explains a case where the bipolar transistor of the amplifier for use in the microwave band illustrated in FIG. 7 is displaced with an FET. In order to improve the input return loss and the gain characteristics in a wide band, the amplifier for use in the microwave band sometimes needs to employ the resistor 931 and the capacitor 932 as RF (high frequency) characteristic adjustment elements, without setting the capacitor 932 to have so large capacitance that the capacitor 932 is substantially short-circuited in an operation band. In the case, in order to suppress the drain current variation due to the Vt variation, the self-bias circuit 930 is required to optimize the resistor 931 with respect to the DC characteristics. However, it was difficult to manage to balance the excellent band characteristics and the current variation characteristics, since the resistor 931 as an RF-characteristics adjustment element has another optimum value for the RF characteristics.

The present invention has been made in view of the above circumstances and provides a field-effect transistor amplifier which comprises a field-effect transistor which amplifies an input signal supplied to a gate terminal thereof and outputs the amplified signal from a drain terminal thereof, and a self-bias circuit coupled to a source terminal of the field-effect transistor. The self-bias circuit comprises a resistor, a capacitor, and an adjusting circuit which adjusts RF (high frequency) characteristics and DC (direct current) characteristics. The resistor, the capacitor, and the adjusting circuit are coupled in parallel with each other, one end of each of which is coupled to the source terminal and the other end of each of which is coupled to the ground.

In the field-effect transistor amplifier according to the present invention, a self-bias circuit is provided with an adjusting circuit coupled in parallel with the resistor and the capacitor and is capable of adjusting RF (high frequency) characteristics and DC (direct current) characteristics; accordingly, it is possible to perform adjustment so that the DC characteristics and the RF characteristics may be both satisfied. As a result, it is possible to manage to balance the excellent band characteristics and the current variation characteristics.

The present invention exhibits an outstanding effect that it is possible to provide a field-effect transistor amplifier which can keep excellent high frequency characteristics and, at the same time, can improve current variation.

### BRIEF DESCRIPTION OF THE DRAWINGS

FIG. 1 is a circuit diagram of a field-effect transistor amplifier according to Embodiment 1 of the present invention;

FIG. 2 is a drawing illustrating DC characteristics of the field-effect transistor amplifier according to Embodiment 1 of the present invention;

FIG. 3 is a drawing illustrating RF characteristics of the field-effect transistor amplifier according to Embodiment 1 of the present invention;

FIG. 4 is a drawing illustrating RF characteristics of the field-effect transistor amplifier according to Embodiment 1 of the present invention;

FIG. 5 is a drawing illustrating the impedance dependence on resistance value of a circuit coupled to a source terminal of an amplification FET of the field-effect transistor amplifier according to Embodiment 1 of the present invention;

FIG. 6 is a circuit diagram illustrating a field-effect transistor amplifier according to Embodiment 2 of the present invention;

FIG. 7 is a circuit diagram of a field-effect transistor amplifier according to Patent Document 1;

FIG. 8 is a circuit diagram of a field-effect transistor amplifier according to a comparative example;

FIG. 9 is a drawing illustrating DC characteristics of the field-effect transistor amplifier according to the comparative example;

FIG. 10 is a drawing illustrating RF characteristics of the field-effect transistor amplifier according to the comparative example;

FIG. 11 is a drawing illustrating RF characteristics of the field-effect transistor amplifier according to the comparative example; and

FIG. 12 is a drawing illustrating the impedance dependence on resistance value of a circuit coupled to a source terminal of an amplification FET of the field-effect transistor amplifier according to the comparative example.

### DETAILED DESCRIPTION OF THE PREFERRED EMBODIMENTS

Hereinafter, embodiments to which the present invention is applied are exemplified. The size and ratio of each member illustrated in the following drawings are only for convenience of explanation, and differ from the actual size and ratio of each member.

### Embodiment 1

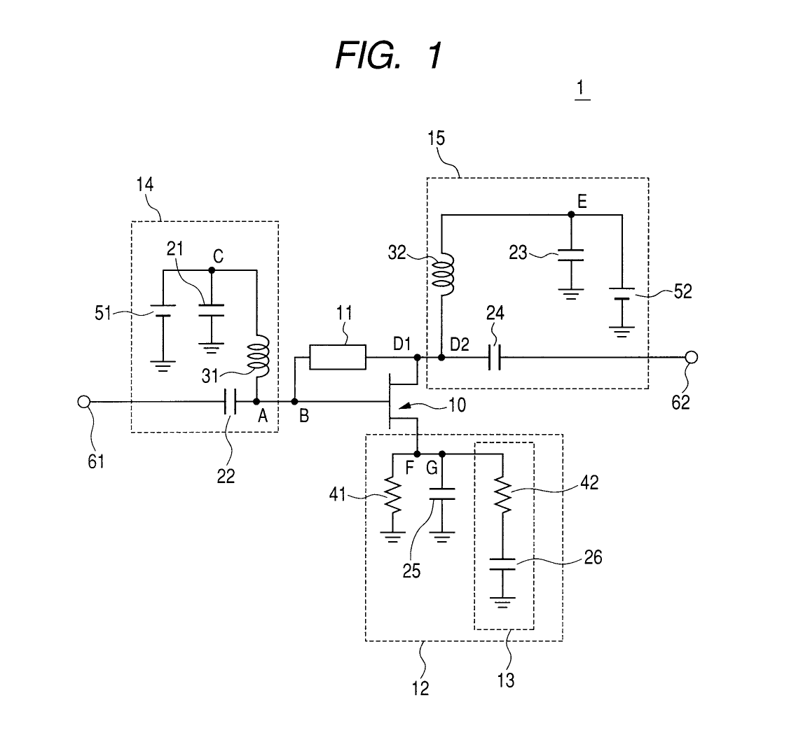

FIG. 1 illustrates a circuit diagram of a field-effect transistor amplifier according to Embodiment 1. As illustrated in FIG. 1, the field-effect transistor amplifier 1 comprises an amplification field-effect transistor (hereinafter called as an “amplification FET”) 10, a feedback circuit 11, a self-bias circuit 12, an adjusting circuit 13, an input matching circuit 14, an output matching circuit 15, an input port 61, and an output port 62.

The feedback circuit 11 is disposed between a gate terminal and a drain terminal of the amplification FET 10. Thereby, an output signal from the drain terminal of the amplification FET 10 is fed back to the input side (the gate terminal).

The self-bias circuit 12 is coupled to a source terminal of the amplification FET 10. The self-bias circuit 12 comprises a current adjusting resistor 41, an RF adjustment capacitor 25, and an adjusting circuit 13, disposed in parallel with each other. One end of each of the current adjusting resistor 41, the RF adjustment capacitor 25, and the adjusting circuit 13 is coupled to the source terminal of the amplification FET 10, and the other end is coupled to the ground.

The adjusting circuit 13 has a function to adjust RF characteristics and DC characteristics. In the adjusting circuit 13, an in-adjusting-circuit resistor 42 and an RF shunt capacitor 26 serving as an in-band shunt capacitor are disposed in series. The in-adjusting-circuit resistor 42 is disposed between the amplification FET 10 and the RF shunt capacitor 26. The RF shunt capacitor 26 is disposed between the in-adjusting-circuit resistor 42 and the ground. What is necessary for the in-band shunt capacitor is just to establish a short circuit sufficiently at least in a use operation band. In Embodiment 1, it is assumed that the in-band shunt capacitor has a large value of capacitance so that it may be short-circuited substantially in a high frequency band.

In the input matching circuit 14, an input shunt capacitor 21, an input DC-cut capacitor 22, an input choke inductor 31, and an input power supply 51 are disposed. The input power supply 51 is disposed between a node C and the ground. The input shunt capacitor 21 is disposed between the node C and the ground. The input DC-cut capacitor 22 is coupled to the input port 61. The other end of the input DC-cut capacitor 22 is coupled to the gate terminal of the amplification FET 10 via a node A and a node B. The input choke inductor 31 is disposed between the node C and the node A. The node A is disposed between the amplification FET 10 and the input port 61.

In the output matching circuit 15, an output shunt capacitor 23, an output DC-cut capacitor 24, an output choke inductor 32, and an output power supply 52 are disposed. The output power supply 52 is disposed between a node E and the ground. The output shunt capacitor 23 is disposed between the node E and the ground. The output DC-cut capacitor 24 is coupled to the output port 62. The output DC-cut capacitor 24 is coupled to the drain terminal of the amplification FET 10 via a node D1 and a node D2. The output choke inductor 32 is disposed between the node D2 and the node E. The node D1 and the node D2 are disposed between the amplification FET 10 and the output port 62.

As described above, it is assumed that the RF shunt capacitor 26 has a large value of capacitance so that it may be short-circuited substantially in an operation band. It is also assumed that the current adjusting resistor 41 has a value of resistance which is optimized to the DC characteristics and which is large enough to sufficiently suppress a drain current variation due to a Vt variation of the amplification FET 10.

It is assumed that the in-adjusting-circuit resistor 42 has a value of resistance optimized to the RF characteristics adjustment performed by the parallel coupling with the RF adjustment capacitor 25. It is also assumed that the RF adjustment capacitor 25 has a value of capacitance optimized for the RF characteristics adjustment.

In FIG. 1, a high-frequency signal of the microwave band supplied to the input port 61 is amplified, according to a gate terminal control voltage supplied via the input matching circuit 14 and a voltage controlled via the output matching circuit 15. The amplified high-frequency signal is fed from the output port 62.

It is only the current adjusting resistor 41 that contributes to the DC characteristics in the circuit coupled between the source terminal of the amplification FET 10 and the ground. Since the value of resistance of the current adjusting resistor 41 is optimized for the DC characteristics, a suitable drain current is obtained. It is also possible to sufficiently suppress the drain current variation due to the Vt variation of the amplification FET 10.

The RF shunt capacitor 26 is short-circuited substantially in the operation band, as described above. Therefore, what contributes to the RF characteristics in the circuit coupled between the source terminal of the amplification FET 10 and the ground is the current adjusting resistor 41, the RF adjustment capacitor 25, and the in-adjusting-circuit resistor 42. The in-adjusting-circuit resistor 42 is adjusted so that the parallel coupling resistance value of the in-adjusting-circuit resistor 42 and the current adjusting resistor 41 may become the most suitable for the RF characteristics. The current adjusting resistor 41 is also assumed to have a value of resistance optimized for the RF characteristics. Therefore, excellent RF characteristics can be obtained. According to the field-effect transistor amplifier according to Embodiment 1 with the above-described configuration, it is possible to manage to balance the excellent band characteristics and the current variation characteristics.

FIG. 8 is a circuit diagram of a field-effect transistor amplifier 101 according to a comparative example. In the following drawings, the same reference symbol is attached to the same member as described above, and the explanation thereof is omitted suitably. A field-effect transistor amplifier 101 according to the comparative example has the same fundamental configuration as that of Embodiment 1 except the following point. That is, the difference is that the adjusting circuit 13 is disposed in Embodiment 1, however, no adjusting circuit is disposed in the comparative example.

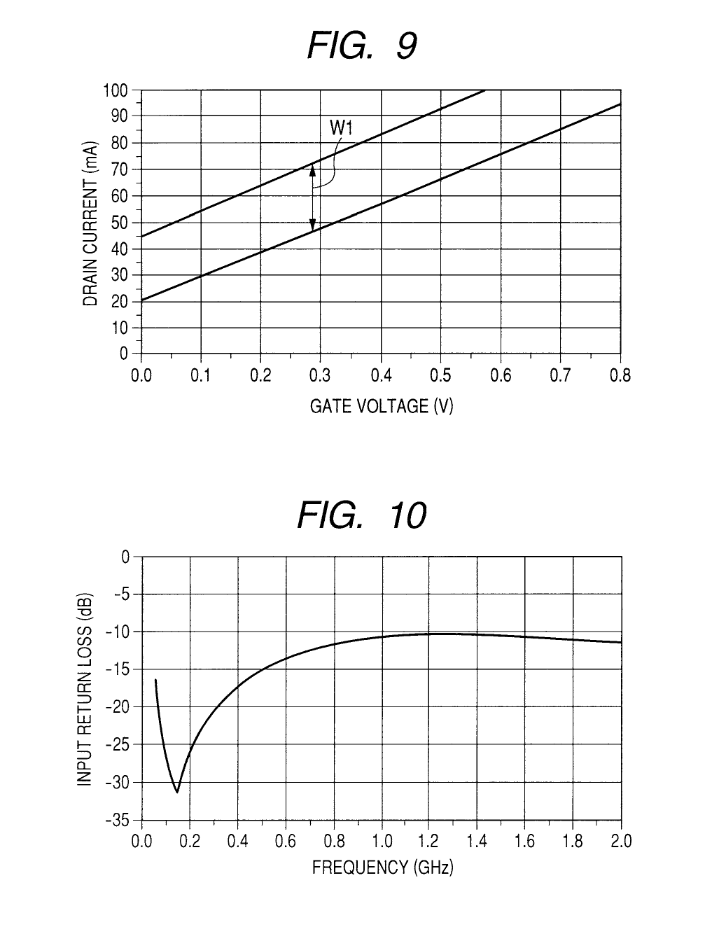

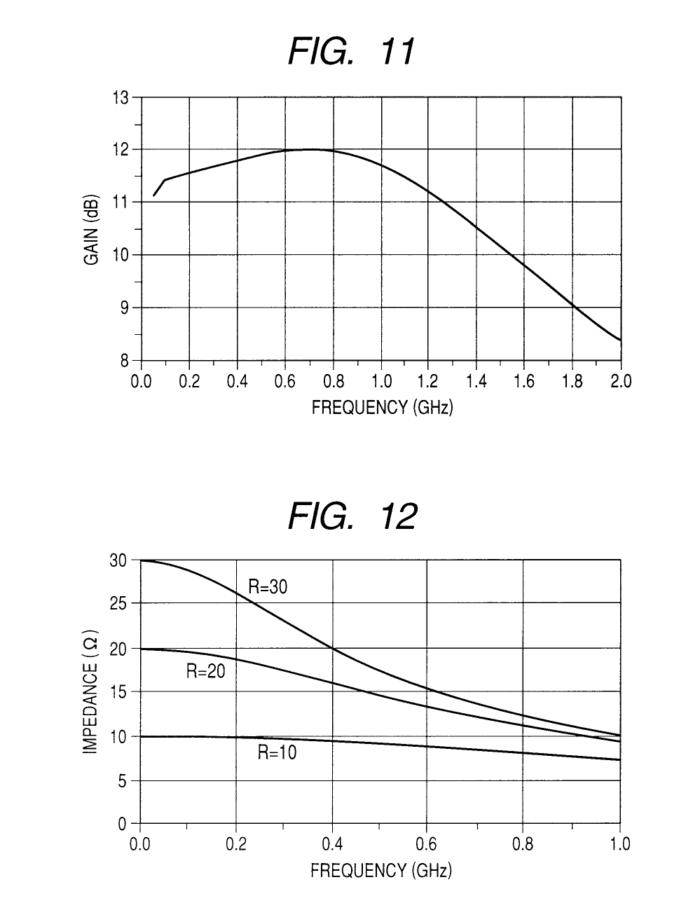

FIG. 9 illustrates DC characteristics plotting a drain current versus a gate voltage of the field-effect transistor amplifier 101 according to the comparative example. FIG. 10 illustrates RF characteristics plotting an input return loss versus frequency of the field-effect transistor amplifier 101. FIG. 11 illustrates RF characteristics plotting a gain versus frequency of the field-effect transistor amplifier 101.

A self-bias circuit 112 of the field-effect transistor amplifier 101 according to the comparative example is optimized to the RF characteristics. Two graphs in FIG. 9 indicate the maximum and the minimum of the drain current in the case of Vt variation of +/−0.15V. A distance between these two graphs gives the range of variation in the drain current. That is, in the field-effect transistor amplifier 101 according to the comparative example, in the case of Vt variation of +/−0.15V, the drain current may be changed in the range indicated by the width W1. From FIG. 9-FIG. 11, it is understood that the field-effect transistor amplifier 101 according to the comparative example exhibits excellent RF characteristics but a large current variation.

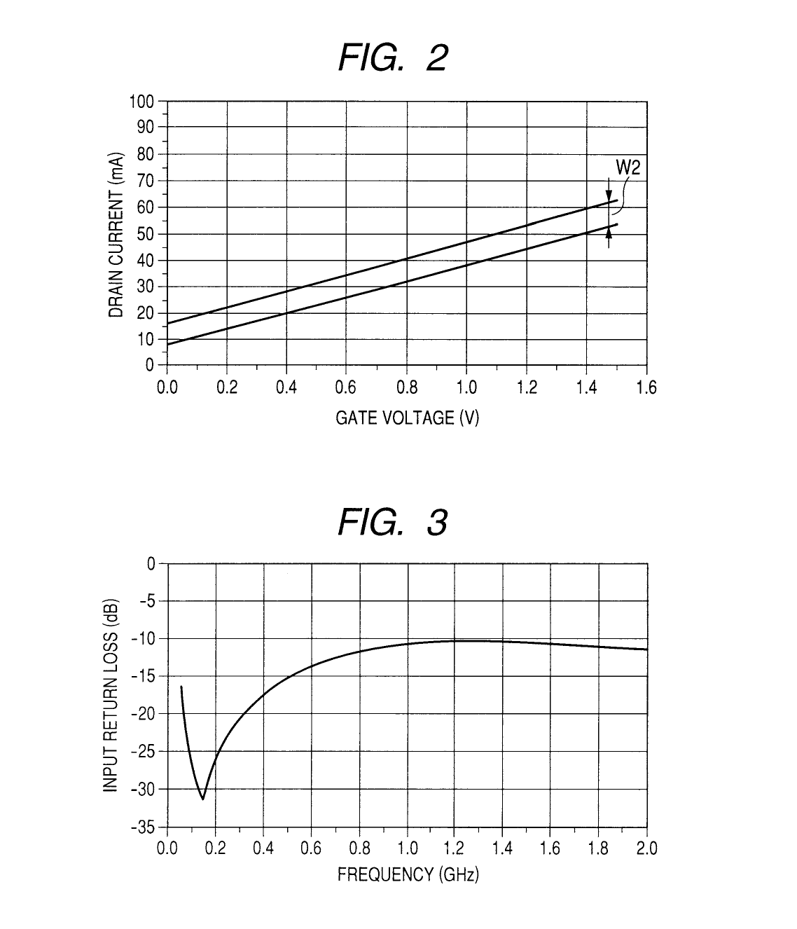

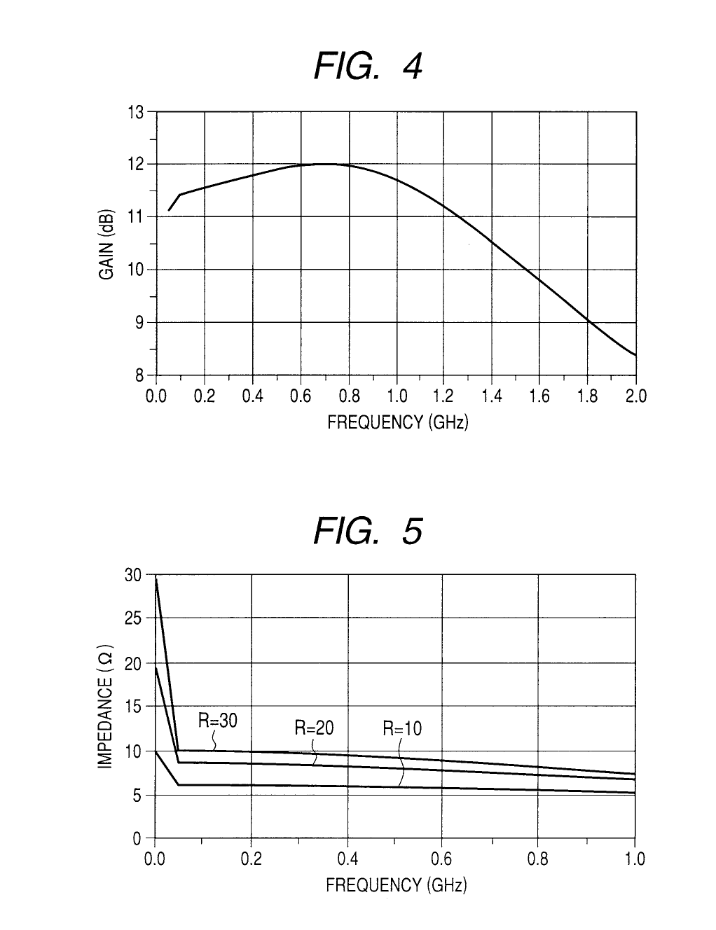

Next, the field-effect transistor amplifier 1 according to Embodiment 1 is explained. FIG. 2 illustrates DC characteristics plotting drain current versus gate voltage of the field-effect transistor amplifier 1 according to Embodiment 1. FIG. 3 illustrates RF characteristics plotting an input return loss versus frequency of the field-effect transistor amplifier 1. FIG. 4 illustrates RF characteristics plotting a gain versus frequency of the field-effect transistor amplifier 1.

Two graphs in FIG. 2 indicate the maximum and the minimum of the drain current in the case of Vt variation of +/−0.15V. That is, in the field-effect transistor amplifier 1 according to Embodiment 1, in the case of Vt variation of +/−0.15V, the drain current may be changed in the range indicated by the width W2. As clearly seen from FIG. 2 and FIG. 9, compared with the comparative example, the field-effect transistor amplifier according to Embodiment 1 can maintain the excellent RF characteristics and suppress the current variation. That is, since the adjusting circuit 13 is provided in Embodiment 1, it is possible to maintain the excellent RF characteristics and to improve the current variation when compared with the comparative example.

Next, the following explains a reason why it is possible, in Embodiment 1, to maintain the RF characteristics and at the same time to suppress the current variation. First, the field-effect transistor amplifier 101 according to the comparative example is explained. FIG. 12 illustrates an impedance dependence on resistance value of the self-bias circuit 112 coupled to the source terminal of the amplification FET 10 in the field-effect transistor amplifier 101 according to the comparative example. The value of capacitance of the RF adjustment capacitor 25 of the self-bias circuit 112 according to the comparative example is fixed to 15 pF. Three conditions of 10 Ω, 20Ω, and 30Ω for the value of the current adjusting resistor 41 are illustrated in FIG. 12.

Here, it is assumed that an impedance of 5-10Ω is necessary in frequency of 50 MHz-1 GHz from a viewpoint of the RF characteristics. On the other hand, a higher impedance is required in order to suppress the current variation with respect to DC. As illustrated in FIG. 12, when the value of resistor R is increased from 10Ω to 30Ω, an increase to 30Ω is realized with respect to DC, however, an impedance in 50 MHz-1 GHz also increases greater than 10Ω; accordingly, the RF characteristics deteriorate.

FIG. 5 illustrates the impedance dependence on resistance value of the self-bias circuit 12 coupled to the source terminal of the amplification FET 10 of the field-effect transistor amplifier 1 according to Embodiment 1. Here, in the self-bias circuit 12 according to Embodiment 1, the value of capacitance of the RF adjustment capacitor 25 is fixed to 15 pF, the value of capacitance of the RF shunt capacitor 26 is fixed to 0.1 μF, and the value of resistance of the in-adjusting-circuit resistor 42 is fixed to 15Ω. Three conditions of 10 Ω, 20Ω, and 30Ω for the value of the current adjusting resistor 41 are plotted in FIG. 5.

Here, it is assumed that an impedance of 5-10Ω is necessary in frequency of 50 MHz-1 GHz from a viewpoint of the RF characteristics. For the value of resistance 30Ω of the current adjusting resistor 41, 30Ω is realized with respect to DC, and an impedance of 5-10Ω is maintained in 50 MHz-1 GHz; accordingly, the RF characteristics do not deteriorate. Therefore, it is possible to maintain the excellent RF characteristics and, at the same time, to suppress the current variation.

According to Embodiment 1, by further coupling, between the source terminal and the ground, the adjusting circuit 13 comprising the in-adjusting-circuit resistor 42 serving as an RF-characteristics adjustment resistor, and the RF shunt capacitor 26 with a sufficiently large capacitance which is short-circuited substantially in the use operation band, it is possible to adjust independently the value of resistance between the source terminal and the ground with respect to each of DC and RF. Therefore, it is possible to maintain the excellent RF characteristics and to improve the current variation when compared with the comparative example.

According to Embodiment 1, it is possible to maintain the excellent RF characteristics and to expand the frequency band where the current variation is excellently suppressed. Therefore, the field-effect transistor amplifier according to Embodiment 1 can be employed suitably especially in a system which needs a wide band.

### Embodiment 2

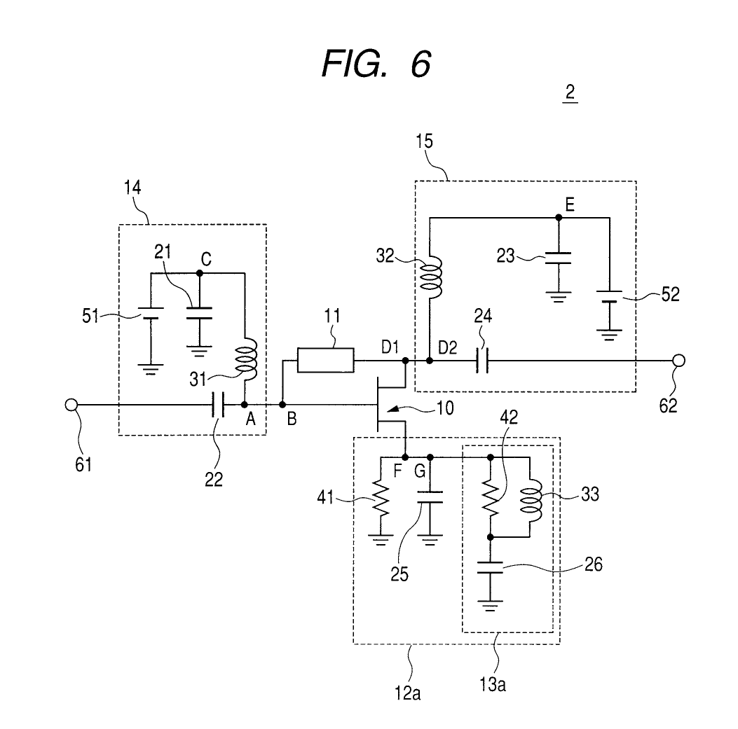

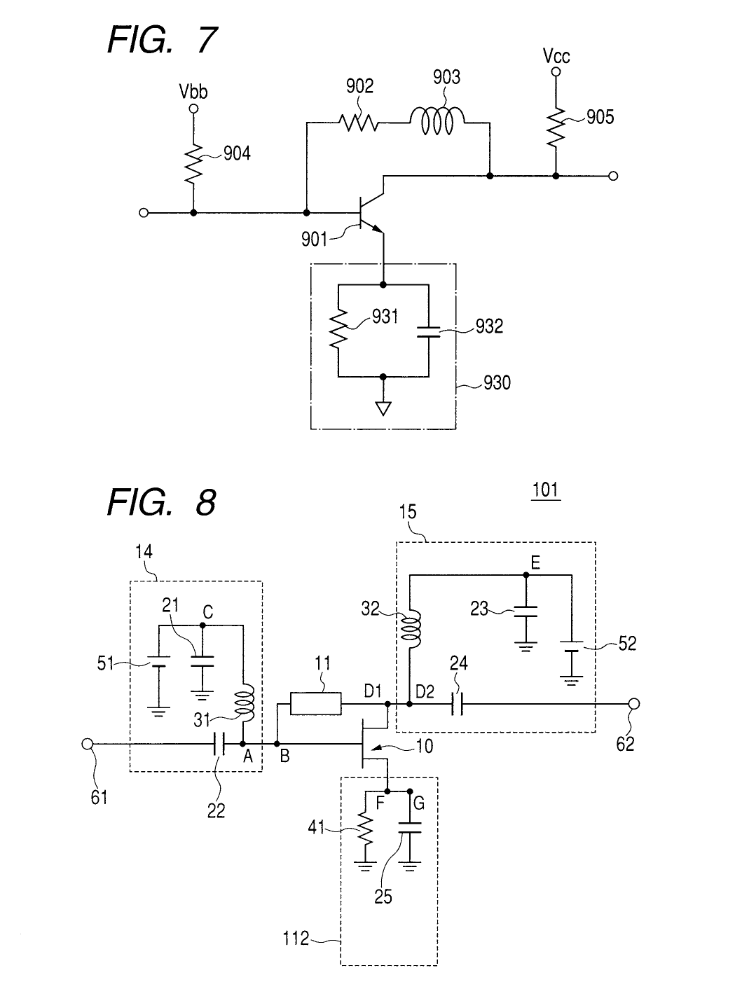

Next, an example of a field-effect transistor amplifier with a configuration different from that of Embodiment 1 described above is explained. FIG. 6 is a circuit diagram illustrating a field-effect transistor amplifier according to Embodiment 2. The fundamental configuration of the field-effect transistor amplifier 2 according to Embodiment 2 is the same as that of Embodiment 1 except the following points. That is, the difference is that, in Embodiment 1, no inductor is disposed in the adjusting circuit 13, on the contrary, in Embodiment 2, an in-adjusting-circuit inductor 33 is disposed in parallel with the in-adjusting-circuit resistor 42 in the adjusting circuit 13a disposed in the self-bias circuit 12a. The in-adjusting-circuit inductor 33 does not contribute to the DC characteristics, but contributes only to the RF characteristics.

According to Embodiment 2, since the adjusting circuit 13a is provided, the same effect as in Embodiment 1 is obtained. According to Embodiment 2, since the in-adjusting-circuit inductor 33 is provided, the design parameters increase; therefore, there is an outstanding merit that degree of freedom in optimizing the RF characteristics increases as compared with Embodiment 1.

The present invention is not limited to Embodiment 1 and Embodiment 2 described above, however, it cannot be overemphasized that another embodiment can belong under the category of the present invention, as long as it agrees with the gist of the present invention. Although the example of an N-type FET has been explained as the amplification FET, the present invention is applicable similarly to a P-type FET. As for each configuration of the self-bias circuit 12 and the adjusting circuit 13, various modifications are possible in a range which does not deviate from the gist of the present invention. As for the configuration other than those of the self-bias circuit 12, the adjusting circuit 13, and the amplification FET 10, various modifications are also possible in a range which does not deviate from the gist of the present invention.

1. A field-effect transistor amplifier comprising:
a field-effect transistor operable to amplify an input signal supplied to a gate terminal and to output the amplified signal from a drain terminal; and
a self-bias circuit coupled to a source terminal of the field-effect transistor,
wherein the self-bias circuit comprises:
a resistor;
a capacitor; and
an adjusting circuit operable to adjust RF (high frequency) characteristics and DC (direct current) characteristics,
wherein the resistor, the capacitor, and the adjusting circuit are coupled in parallel with each other, one end of each of which is coupled to the source terminal and the other end of each of which is coupled to a ground.

2. The field-effect transistor amplifier according to claim 1,
wherein the adjusting circuit comprises: an in-band shunt capacitor which is substantially short-circuited at least in a use operation band; and an in-adjusting-circuit resistor, and
wherein the in-adjusting-circuit resistor is disposed between the source terminal and one end of the in-band shunt capacitor, and the other end of the in-band shunt capacitor is coupled to the ground.

3. The field-effect transistor amplifier according to claim 2,
wherein the adjusting circuit further comprises an in-adjusting-circuit inductor which is coupled to the in-adjusting-circuit resistor in parallel and coupled to the in-band shunt capacitor in series.

4. The field-effect transistor amplifier according to claim 2.
wherein the in-band shunt capacitor is an RF shunt capacitor.

5. The field-effect transistor amplifier according to claim 3,
wherein the in-band shunt capacitor is an RF shunt capacitor.
